(19) United States
(12) Patent Application Publication
(10) Pub. No.: US 2026/0319996 A1
(43) Pub. Date: Oct. 15, 2026

(54) A COMPUTATION PLATFORM FOR AUTOMOTIVE APPLICATIONS

(71) Applicant: EVNXS ADAMO AB, Göteborg (SE)

(72) Inventors: Rolf JOHANSSON, Mölndal (SE); Markus DERNEVIK, Billdal (SE); Anton FORS, Mölndal (SE)

(21) Appl. No.: 19/112,017

(22) PCT Filed: Sep. 13, 2023
(86) PCT No.: PCT/EP2023/075093

§ 371 Date: Mar. 14, 2025

(30) Foreign Application Priority Data
Sep. 19, 2022 (SE) 2230296-2

(51) Int. Cl. G06F 15/78; G06F 9/50

(52) U.S. Cl. CPC G06F 15/7871; G06F 9/5005

(57) ABSTRACT

An upgradeable architecture (300) for compute-intensive automotive applications, comprising at least two replaceable resource modules (310), one or more replaceable frame modules (320) arranged to receive one or more of the resource modules (310) and to provide an interface between the resource modules and a physical backplane connection (330), and also a resource allocation mechanism (340) arranged to allocate compute tasks and system resources between the replaceable resource modules (310).

### TECHNICAL FIELD

The present disclosure relates to hardware architectures and systems for compute-intensive automotive applications.

### BACKGROUND

Technical progress in the automotive field is fast and keeps accelerating. New functions are being released more or less continuously, for applications such as advanced driver assistance (ADAS), autonomous drive (AD), and electric drivetrain control. A drawback of this fast-paced technical progress and increasing complexity in automotive information handling is that automotive computing platforms may become obsolete much faster than the rest of the hardware in, e.g., a car or truck, such as its chassis, electric machines, and battery system.

There is a need for a paradigm shift in how computation platforms for automotive applications are designed.

### SUMMARY

It is an objective of the present disclosure to provide new hardware architectures and system designs which are better suited for the type of fast technical progress seen in the automotive industry today. This objective is obtained at least in part by an upgradeable architecture for compute-intensive automotive applications. The architecture, which is a form of compute system that can be deployed in a road vehicle such as a car or a truck, comprises one or more replaceable resource modules that may encapsulate, e.g., brake functionality, data storage or sensor functions for object detection. The architecture also comprises one or more replaceable frame modules arranged to receive one or more of the resource modules and to provide an interface between the resource modules and a physical backplane connection, where the physical backplane connection may advantageously be arranged to provide a homogenous interface between resource modules and a data backbone of a vehicle. The upgradeable architecture also comprises a resource allocation mechanism which is arranged to allocate compute tasks and system resources between the replaceable resource modules. This upgradeable architecture allows a vehicle designer or compute system developer to replace resource modules over time in response to, e.g., changes in requirements, updates in the design of the vehicle, and availability of new technologies, such as new sensors, by simply replacing the resource modules in the frame, whereby, in some examples, they will be discovered and managed by the resource allocation mechanism. More resource modules can also be added over time, which is an advantage. Notably, the frames themselves are also replaceable, which means that the form factor of the compute architecture and connections to the backplane of the vehicle is adaptable to new requirements and to fit different vehicle types. By providing upgradability in two tiers in this manner, i.e., on the resource module level and on the frame level, additional degrees of freedom are provided to both the vehicle designer and to the vehicle compute task developer.

The resource allocation mechanism optionally implements a dynamic resource discovery mechanism, i.e., a resource discovery mechanism which is operative to dynamically discover new resources in the system. This dynamic resource discovery mechanism may operate on different time scales, such as per task, per service upgrade event, or per software upgrade release. In other words, dynamic is to be construed in a broad sense herein. Its general purpose is to discover what resources are currently available in the instantiation of the overall architecture and allocate compute tasks and system resources accordingly. The resource allocation mechanism may reside in the architecture itself, such as on a resource module inserted into one of the frames, or it can be located outside of the architecture.

A resource discovery mechanism as described above can also be used to determine that the instantiation of the architecture in a vehicle is in a known good state during system initialization. This can be used to determine if the vehicle can be safely operated, improve diagnostics capability and to detect potential hardware or software faults that might necessitate a workshop visit or a remote software update.

According to an example of this resource allocation mechanism, it also implements functionality to detect when an error occurs which necessitates a re-allocation of compute tasks within the architecture. For instance, a resource module may malfunction, and the resource allocation mechanism then triggers a re-organization of executing tasks to mitigate consequences of the malfunction event. This example is particularly relevant for the type of dynamic resource allocation mechanisms which are dynamic on the shorter time scales, e.g., on a drive cycle basis.

The replaceable resource modules optionally also comprise a wire harness interface arranged to communicatively couple the replaceable resource module to one or more external devices. This means that external devices can connect directly to the resource modules, and not necessarily to some intermediate device. Thus, interfaces to external devices are very flexible, and can be replaced by replacing the corresponding resource module implementing the interface. It is noted that both hardware components and software components can be replaced in this manner. I.e., the physical connectors and the transceivers, as well as drivers and other software components associated with the interface. In other words, a replaceable resource module may also comprise at least one physical transceiver with associated transceiver drive logic and link management function.

According to an example, the upgradeable architecture also comprises an integration controller module arranged to interconnect one or more external electronic control units (ECU) to the physical backbone connection. This integration controller module can be used, e.g., to support legacy (previously developed and released) hardware and software.

According to another example, the architecture control system is configured to provide communication between service-based and signal-based applications through a service interface layer. This way the architecture control system is able to provide both deployment of applications and configuration of communication between applications. In fact, any high-level communication paradigm can be used in this context, such as client-server, publisher-subscriber, remote procedure call (RPC), or a topic-based paradigm, which is an advantage.

Vehicles, computer programs, computer readable media, and computer program products associated with the above discussed advantages are also disclosed herein.

Generally, all terms used in the claims are to be interpreted according to their ordinary meaning in the technical field, unless explicitly defined otherwise herein. All references to “a/an/the element, apparatus, component, means, step, etc.” are to be interpreted openly as referring to at least one instance of the element, apparatus, component, means, step, etc., unless explicitly stated otherwise. The steps of any method disclosed herein do not have to be performed in the exact order disclosed, unless explicitly stated. Further features of, and advantages with, the present invention will become apparent when studying the appended claims and the following description. The skilled person realizes that different features of the present invention may be combined to create embodiments other than those described in the following, without departing from the scope of the present invention.

### BRIEF DESCRIPTION OF THE DRAWINGS

The above, as well as additional objects, features and advantages, will be better understood through the following illustrative and non-limiting detailed description of exemplary embodiments, wherein:

FIG. 1 shows an example vehicle;

FIG. 2 illustrates an information handling system for a vehicle;

FIG. 3 schematically illustrates an example computation platform;

FIG. 4 conceptually illustrates resource modules received in a frame;

FIG. 5 illustrates software execution on a computation platform;

FIG. 6 shows an example architecture realization;

FIG. 7 is a flow chart illustrating methods;

FIG. 8 schematically illustrates a control unit; and

FIG. 9 shows an example computer program product.

### DETAILED DESCRIPTION

The present disclosure will now be described more fully hereinafter with reference to the accompanying drawings, in which exemplary embodiments are shown. The disclosure may, however, be embodied in many different forms and should not be construed as limited to the embodiments set forth herein; rather, these embodiments are provided for thoroughness and completeness. Like reference character refer to like elements throughout the description.

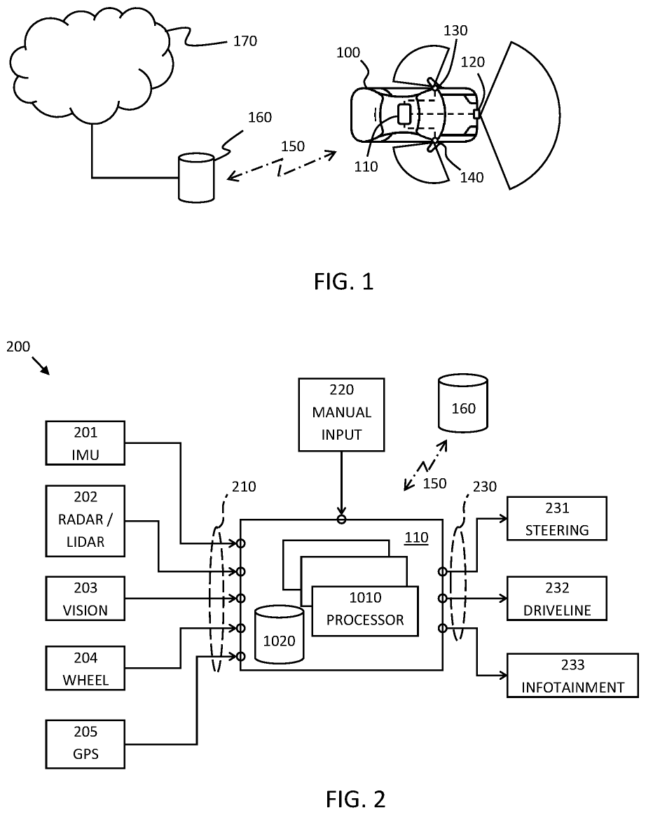

FIG. 1 illustrates a general road vehicle 100 where various automotive compute-intensive applications are executed by one or more computation platforms 110. The example vehicle 100 comprises a computation platform 110 arranged to process signals from a front view sensor 120, such as a radar, a lidar, or a vision-based sensor, and also signals from side-view sensors 130, 140. The vehicle 100 also comprises communication systems for communicating over wireless link 150 with external entities such as remote servers 160 and cloud-based resources 170.

FIG. 2 provides an overview 200 of the compute-intensive processing operations performed in a modern road vehicle. Input data 210 is received periodically or continuously from data sources such as inertial measurement units (IMU) 201, radar and lidar transceivers 202, vision-based sensors such as cameras 203, wheel speed sensors 204 and satellite-based positioning systems 205, just to name a few. The constituent data streams of the aggregated input 210 to the computation platform 110 are often of a high rate, and often tailored for a specific type of vehicle. The computation platform 110 normally also accepts various forms of manual input 220. Some implementation details of the processing circuitry 810 and memory storage components 820 of the computation platform 110 will be discussed in more detail below in connection to FIG. 8.

A result of the processing performed on the computation platform 110 could be, e.g., control output signals 230 which actuate various devices on the vehicle 100, such as its steering 231, the driveline 232, and also less safety critical systems such as on-board infotainment systems 233.

A drawback with most computation platforms deployed in road vehicles today is that they are built on vehicle specific hardware. The software executing on the computation platform may be upgradeable, and normally is, but it is difficult or even impossible to reconfigure the compute resource hardware, i.e., the processing hardware, the physical interfaces of the computation platform, its physical dimensions and mounting, the different wire harnesses, and so on. This makes it hard to keep an existing road vehicle competitive in terms of functionality, e.g., since new sensor systems are constantly being developed. By designing a computation platform which not only executes upgradeable software but is also upgradeable in terms of computation hardware and physical details such as wire harnesses and mechanics, the vehicle 100 is more likely to maintain its value and competitiveness over a longer period of time. The platform also offers a degree of abstraction which obviates the need for platform dependent design.

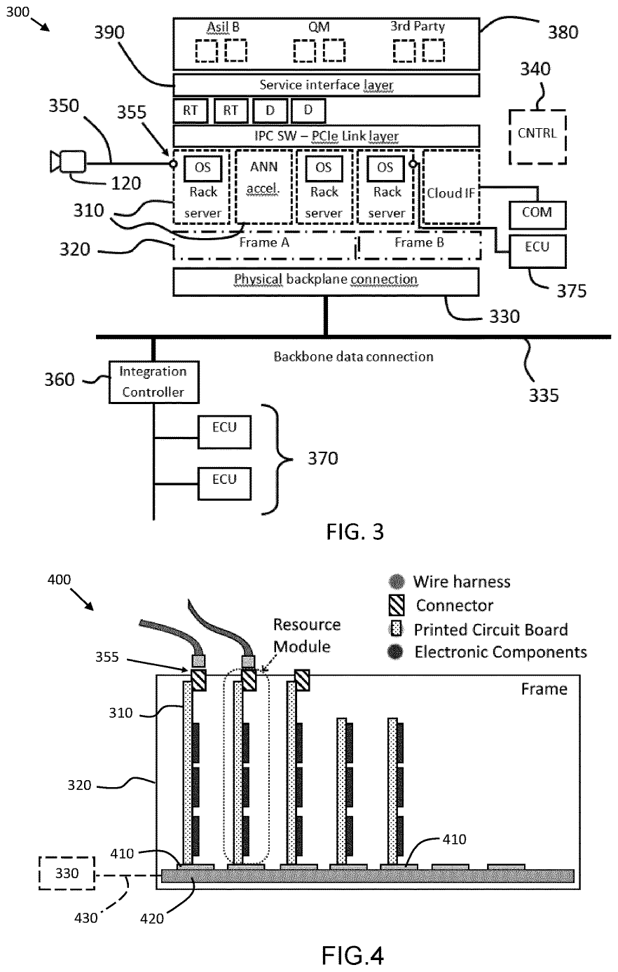

FIG. 3 schematically illustrates a computation platform which is upgradeable in terms of both its hardware, software, interfaces, and mechanics. This platform alleviates or even solves some of the issues associated with vehicle-specific computation platforms in road vehicles today.

Hardware in the form of resource modules is upgradeable by, for instance, substituting them with a resource module with more resources or a broader range of capabilities.

Upgradeability or replacement of, for example, externally sourced electrical components or subsystems, is enabled by replacing the hardware and/or software component, that might reside on or constitute a resource module, that is responsible for the encapsulation of that component or subsystem. Software is upgradeable in the same way as hardware, by replacing the software or part of the software. Note that the flexibility in computing resources provided by the resource modules allows a complete re-allocation of all software entities to the, at the upgrade time, most suitable computing resources provided by resources module. This re-allocation might also be driven by a change in resources, not only by a change in in software and the associated computing need.

Interfaces to for example functions, components and subsystems can be upgraded at both sides of the encapsulation layer, which provides the possibility to replace a physical component of the compute system while maintaining a harmonized interface to the rest of the vehicle.

More specifically, FIG. 3 illustrates an upgradeable architecture 300 for compute-intensive automotive applications, comprising one or more replaceable resource modules 310 (illustrated by dashed line boxes). The compute system in FIG. 3 also comprises one or more replaceable frame modules 320 (illustrated as dash-dotted boxes) arranged to receive one or more of the resource modules 310 and to provide an interface between the resource modules and a physical backplane connection 330. The upgradeable architecture 300 also comprises a resource allocation mechanism 340 arranged to allocate inbound compute tasks between the replaceable resource modules 310. The architecture 300 has a form factor which can be matched to available vehicle space, this means that it can be adapted to fit into a given vehicle and connect to more or less arbitrary wire harness types. Then, if said vehicle is to be redesigned for some reason, the architecture 300 can be re-formatted to fit into the new vehicle design, including updating of physical interfaces, wire harness transceivers, and mechanics.

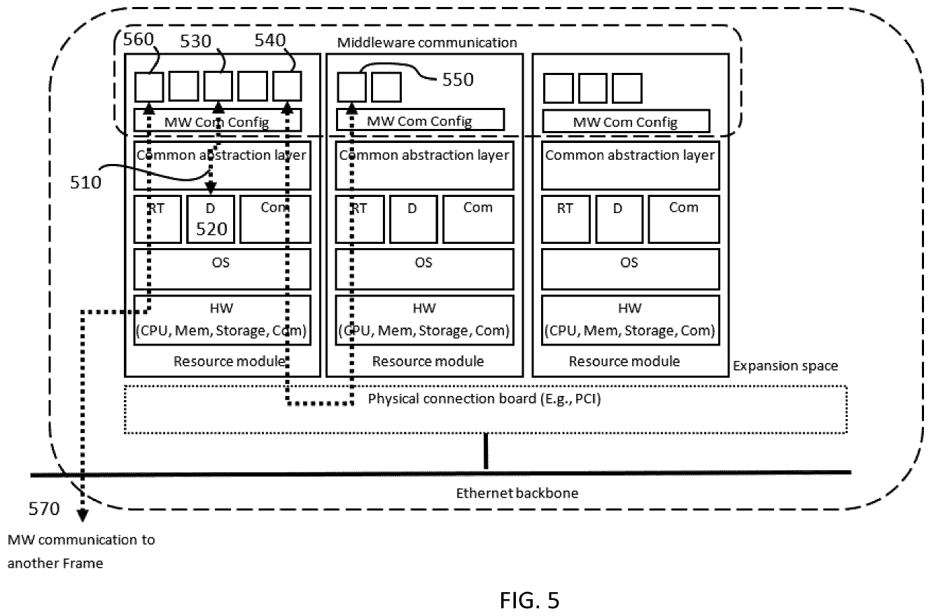

According to some examples, a resource module can be seen as a discrete component of a system that handles specific resources or provides a particular functionality. This might encapsulate a particular capability, e.g., a brake function, file storage, or a sensor function for object detection, along with corresponding software abstractions. A resource module may also encapsulate computing resources, e.g., memory, computing cores, and partitions, that can be directly used by software components deployed to a common middleware. This means that the resource module is allowed by the resource allocation mechanism as deployment target for software components. An important part of the resource module may relate to communication encapsulation, i.e., that a gateway or protocol translation mechanism allows communication to and from the resource module via a communication backbone. This communication backbone will be discussed in more detail below in connection to FIG. 5.

According to related examples, a frame module can be seen as a module that contains one or several resource modules according to the discussion herein, in a predefined mechanical structure and with a standardized electrical connection. This may be an important part of encapsulating third party resources to allow for an incremental evolution of the electrical platform, as well as an important part of the system communication backbone, i.e., the main communication bus of the system, that could consist of any number of technologies, e.g., TCP/IP, SOME/IP, MTQQ on ethernet.

One of the novelties of the upgradeable architecture 300 is that it uses a two-tier hierarchy of replaceable units; the resource modules 310 make up one level. The resource modules are then placed within one or more frames 320, that make up the second level. One, or several frames are supported. Frames can communicate within a shared middleware or can have a separate middleware domain of their own. Each frame 320 then interfaces physically to the backplane connection 330, which in turn connects to a backbone data connection 335, such as an Ethernet network or the like.

In this context, a backplane 330 is a group of electrical connectors forming a computer bus. A backbone 335, herein, is the top level of a hierarchical vehicle computer network, often of high speed and capacity, such as an optical fibre link or the like.

The resource allocation mechanism 340 optionally also implements a dynamic resource discovery mechanism. This dynamic resource discovery mechanism preferably executes on-board the road vehicle 100 in a dynamic manner, either continuous, per drive cycle, per SW update, or triggered by diagnostic command. The resource discovery mechanism keeps track of the current state of the upgradeable architecture 300, in terms of the installed base when it comes to resource modules, frames, interfaces, rivers, and so on. This mechanism makes it convenient to deploy software on the platform, since this software can call on available compute resources from the discovery mechanism.

A dynamic resource discovery mechanism is generally a mechanism arranged to locate and utilize resources on a network, which allows resources to be discovered dynamically at runtime and/or at start-up. The term “dynamic resource discovery mechanism” is a well-known term in the technical field of computer architecture, where it is sometimes also known as service discovery mechanism. Examples of such mechanisms are (using abbreviations well-known in the field): zeroconf, UPnP, SLP, DNS-SD, Consul, Jini, Kubernetes SD, and SOME/IP SD.

A main advantage of dynamic resource discovery is that intermittent availability of certain resources, e.g., cloud connection, can be made known to functions using said resources with minimal overhead. In some realizations the resource allocation mechanism 340 operates on a much slower timescale of months or even years, such as each time the vehicle is serviced, or each time the vehicle undergoes a major upgrade event. In this case the resource allocation mechanism 340 may be arranged on a platform external to the vehicle, such as on a compute-platform in a vehicle workshop or at a dealer.

This modular and upgradable computing resource architecture enables interfacing to tier 1 supplier off-the-shelf ECUs 370, 375. At the same time independence from supplier ECUs is maximized by localizing the physical and functional interface to the supplier ECU in a single resource module, located in in the OEM-controlled frame. The architecture also enables flexible and modular communication between applications based on highly abstracted middleware communication, e.g., service-based applications, and signal-based applications using classical automotive communication paradigms, by way of a communication abstraction and the encapsulated interfaces provided for sensors, actuators, supplier ECUs, or OEM controlled real-time and high-integrity SW components. The abstracted interfaces are generated and proven safe in a generalized offboard Continuous Integration (CI), also ensuring that contractual relationships between design entities are upheld.

Physical wire harness contacting is an important part of a communication resource, but bus transceivers and drivers are also important to consider. By implementing a flexible computation platform architecture where wire harnesses can be easily replaced, support for a new bus-type is easily added, even if the new bus-type is totally unknown at the time of original deployment of the computation platform 300. The resource module 310 may implement both physical connector, transceiver, and driver, and also an encapsulated application programming interface (API) on the application layer or in the configuration module of the resource module 310.

Any number of replaceable resource modules 310 may comprise a wire harness interface 355, as exemplified in FIG. 3. This interface is then arranged to communicatively couple 350 the replaceable resource module 310 to an external device 120. In the example of FIG. 3, a vision-based sensor 120 has been added to the road-vehicle control system. The output data from this sensor is received via the harness directly to the resource module implementing support for the sensor. If the sensor is to be replaced, the associated resource module in the architecture can be replaced at the same time, thus avoiding any interfacing problems with a new sensor replacing the previous one, since a new resource module can be added which has the appropriate wire harness interface. An advantage associated with connecting a wire harness directly to a resource module in this manner is that the computation platform does not need connectors on its outer frame, i.e., casing. FIG. 4 illustrates an example 400 of replaceable resource modules 310 that comprise this type of wire harness interface 355. As illustrated in the Figure, wire harnesses interface directly to the resource modules via connectors.

Herein, “replaceable”, as in “replaceable resource module 310″ and ” replaceable frame module 320″ means that a resource module 310 or a frame module 320 can be removed from the upgradeable architecture 300, i.e., the automotive compute system, without also removing and/or modifying other components of the same type. Thus, a replaceable resource module 310 is arranged to be removed from the architecture 300 without modifying any of the other resource modules 310 or frame modules 320. Likewise, a replaceable frame module 320 is arranged to be removed from the architecture 300 without modifying any of the other resource modules 310 (received in other frames) or other frame modules 320. A new resource module 310 or frame module 320 not previously part of the architecture 300 can also be added to the architecture without modifying existing components. A replaceable module (resource module or frame module) in the architecture can be removed and then replaced by a new module, or a new module can be added without first removing an old module, or an existing module can be removed without adding a new module, all without modification to other modules in the system. With this definition of “replaceable”, it becomes clear that the architecture is conveniently upgradeable since a resource module or frame module can be removed from the architecture without also modifying or removing any other modules.

WO2000018614A1 discloses an upgradeable computer architecture for automotive applications. The architecture in WO2000018614A1 comprises a mechanical enclosure that can accommodate computer system modules similar to video game cartridges. The computer system modules are self-contained modules having pre-loaded software and hardware that can be used to perform a variety of functions. Thus, it is understood that each module has a module specific software and is only capable of supporting this module specific function. Compute tasks cannot be allocated between modules as in the present architecture.

FIG. 4 provides an example 400 of how a resource module 310 can be made replaceable in practice. In this example the resource modules 310 are printed circuit board (PCB) units inserted into slots 410 supported by a carrier 420 comprised in the frame module 320. The slots 410 provide, e.g., power to the resource module 310 and also connects 430 the resource module 310 to the physical backplane 330 discussed above in connection to FIG. 3.

According to the same philosophy, at least one of the replaceable resource modules 310 comprises at least one physical transceiver with associated transceiver drive logic and link management function. Again, since the resource module implements the transceivers and associated drive logic, the overall architecture becomes much less sensitive to paradigm shifts in automotive on-board communication standards.

The upgradeable architecture 300 exemplified in FIG. 3 also comprises an optional integration controller module 360 arranged to interconnect one or more external ECUs to the physical backplane connection 330. An integration controller is a communication gateway translating between automotive busses, e.g., CAN, LIN, and the backbone communication protocol, e.g., UDP. It is appreciated that the architecture 300 decreases the need for integration controllers, as both contacting and automotive bus control can be handled by the resource modules. Integration controllers are nevertheless supported if needed, e.g., for wire harness optimization. Note that a resource module 310 may also interface directly with an ECU 375, i.e., the integration controller may be comprised as part of a resource module 310.

The architecture control system 340 configures the communication between, on one side, application using the middleware abstraction, e.g., service-based applications 380, and, on the other side, applications or physical resources in the physical vehicle using signal-based communication. This is done by means of an abstraction layer, e.g., a service interface layer, provided by the architecture control system 340. I.e., the architecture control system 340 provides both deployment of applications and configuration of communication between applications. An application, in this context, can for instance be a software component or binary for driver personalization. An application can also be an algorithm for controlling a brake blending operation by the vehicle 100. In fact, any high-level communication paradigm can be used in this context, such as client-server, publisher-subscriber, remote procedure call (RPC), or a topic-based paradigm.

FIG. 5 illustrates an extendable central computing platform for road vehicles that contains several computers joined together by a common middleware providing a software abstraction of the computing and communication resources provided by the computers. The software abstraction provides service interfaces of the underlying resources to the application software components using them. Realtime software is supported by direct deployment to the computers. The computers providing the resources might be interchanged or extended by adding more. The computers need not be identical but can provide specialized resources. The computers typically have their OS, processor(s), working and storage memory and communication interfaces (physical connectors, IO drivers, bus transceivers and drivers), but might also be operating system (OS) less microcontroller units (MCU).

In FIG. 5, examples of communication paths are shown with dotted lines with arrow endpoints.

Example 1 shows communication 510 between a lower level ASIL D software component 520 deployed directly to the Resource module's OS, and a higher-level software component 530 on the abstraction layer. This software component is running on the same resource module but communicates through the abstraction layer.

Example 2 shows communication between two software components 540, 550, both conceptionally on the abstraction layer, but physically deployed to two different resource modules. The encapsulation of the communication through the lower abstraction layers, is configured by the resource allocation mechanism 340, and is transparently handled by the middleware abstraction.

Example 3 shows a similar set-up as example two, except that in this case communication is between software components 560, 570 deployed on different resource modules in different frames. Note that several ECUs are comprised in the compute system. These ECUs can be legacy ECUs or supplier provided ECUs.

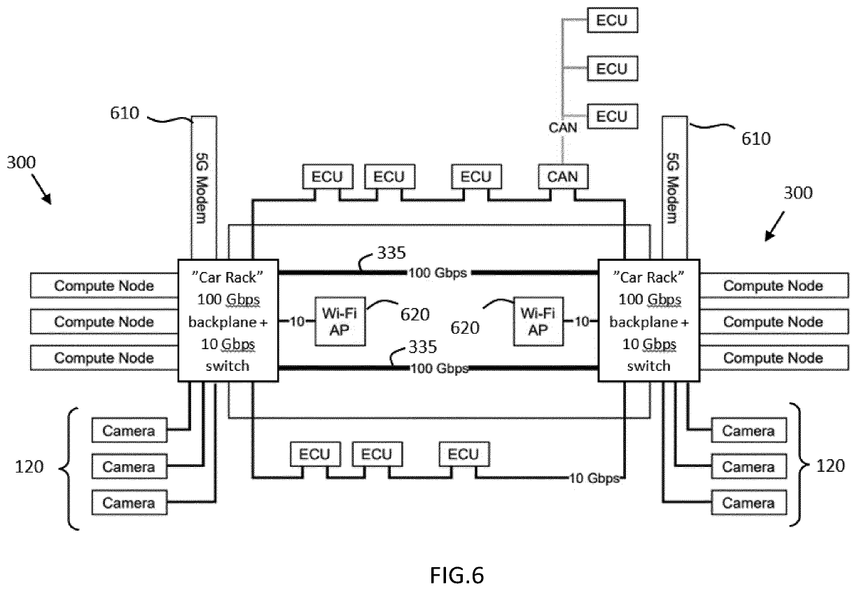

FIG. 6 illustrates a physical network topology for an embodiment of the architectural pattern discussed above. The upgradeable architecture 300 discussed above has here been instantiated two times and uses a 100 Gbps backbone connection for communication in-between. A 5G model 610 provides cellular access in each of the architectures 300, and Wi-Fi access points (AP) 620 provide local Wi-Fi connectivity.

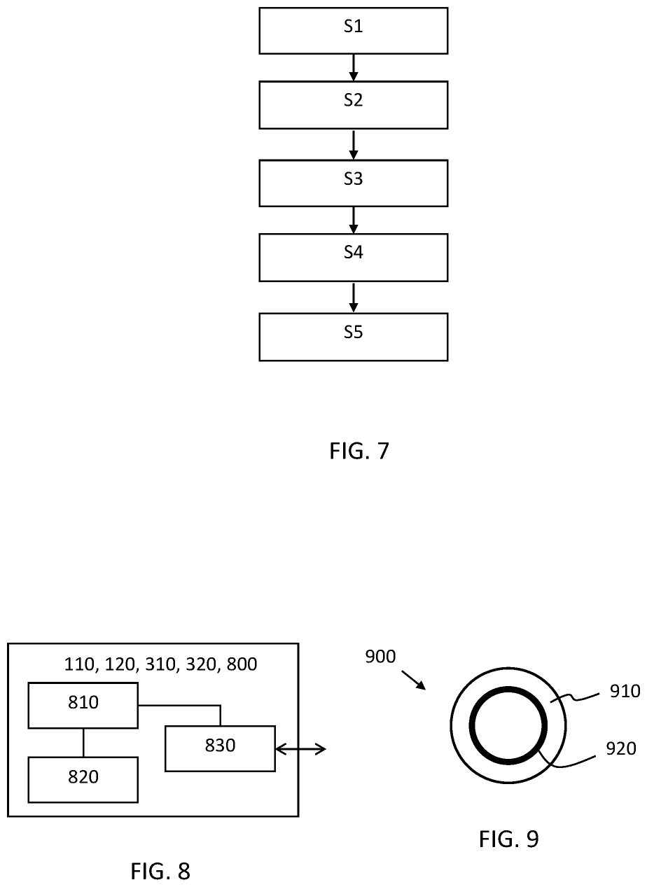

The above discussion can be summarized in terms of a method, which is illustrated by the flow chart in FIG. 7. FIG. 7 illustrates a method for performing compute-intensive automotive applications. The method comprises providing S1 one or more replaceable resource modules 310 as well as providing S2 one or more replaceable frame modules 320. The method also comprises connecting S3 each of the one or more resource modules 310 to a respective frame module (320) and connecting S4 an interface between each of the resource modules 310 and a physical backplane connection 330. The method further comprises allocating S5 compute resources of the replaceable resource modules 310 by a resource allocation mechanism 340 configured to allocate compute tasks and system resources of the compute-intensive automotive applications to the replaceable resource modules 310.

FIG. 8 schematically illustrates, in terms of a number of functional units, the components of a control unit 110, 120, 310, 320, 800 according to embodiments of the discussions herein. Processing circuitry 810 is provided using any combination of one or more of a suitable central processing unit CPU, multiprocessor, microcontroller, digital signal processor DSP, etc., capable of executing software instructions stored in a computer program product, e.g., in the form of a storage medium 830. The processing circuitry 810 may further be provided as at least one application specific integrated circuit ASIC, or field programmable gate array FPGA. Particularly, the processing circuitry 810 is configured to cause the control unit 110, 120, 310, 320, 800 to perform a set of operations, or steps, such as the methods discussed in connection to FIG. 7 and generally herein. For example, the storage medium 830 may store the set of operations, and the processing circuitry 810 may be configured to retrieve the set of operations from the storage medium 830 to cause the control unit 110, 120, 310, 320, 800 to perform the set of operations. The set of operations may be provided as a set of executable instructions. Thus, the processing circuitry 810 is thereby arranged to execute methods as herein disclosed.

The storage medium 830 may also comprise persistent storage, which, for example, can be any single one or combination of magnetic memory, optical memory, solid state memory or even remotely mounted memory.

The control unit 110, 120, 310, 320, 800 may further comprise an interface 820 for communications with at least one external device. As such the interface 820 may comprise one or more transmitters and receivers, comprising analogue and digital components and a suitable number of ports for wireline or wireless communication.

The processing circuitry 810 controls the general operation of the control unit 110, 310, 320, 800, e.g., by sending data and control signals to the interface 820 and the storage medium 830, by receiving data and reports from the interface 820, and by retrieving data and instructions from the storage medium 830. Other components, as well as the related functionality, of the control node are omitted in order not to obscure the concepts presented herein.

FIG. 9 illustrates a computer readable medium 910 carrying a computer program comprising program code means 920 for performing the methods illustrated in FIG. 9 and the techniques discussed herein, when said program product is run on a computer. The computer readable medium and the code means may together form a computer program product 900.

1. An upgradeable architecture for compute-intensive automotive applications, comprising
one or more replaceable resource modules,
one or more replaceable frame modules arranged to receive one or more of the resource modules and to provide an interface between the resource modules and a physical backplane connection, and also
a resource allocation mechanism arranged to allocate compute tasks and system resources between the replaceable resource modules.

2. The upgradeable architecture according to claim 1, where the resource allocation mechanism also implements a dynamic resource discovery mechanism.

3. The upgradeable architecture according to claim 1, where at least one of the replaceable resource modules comprises a wire harness interface arranged to communicatively couple the replaceable resource module to an external device.

4. The upgradeable architecture according to claim 1, where at least one of the replaceable resource modules comprises at least one physical transceiver with associated transceiver drive logic and link management function.

5. The upgradeable architecture according to claim 1, comprising an integration controller module arranged to interconnect one or more external electronic control units, ECU, to the physical backplane connection.

6. The upgradeable architecture according to claim 1, where the architecture control system is configured to provide communication between service-based and signal-based applications through a service interface layer.

7. The upgradeable architecture according to claim 1, where at least one of the replaceable resource modules is configured to emulate one or more software functions of a legacy ECU.

8. The upgradeable architecture according to claim 1, where at least one of the replaceable resource modules comprises one or more interfaces adapted to emulate one or more hardware interfaces of a legacy ECU.

9. A vehicle comprising an upgradeable architecture according to claim 1.

10. A method for performing compute-intensive automotive applications, the method comprising
providing (S1) one or more replaceable resource modules,
providing (S2) one or more replaceable frame modules,
connecting (S3) each of the one or more resource modules to a respective frame module, and
connecting (S4) an interface between each of the resource modules and a physical backplane connection,
the method further comprising
allocating compute resources of the replaceable resource modules by a resource allocation mechanism configured to allocate compute tasks and system resources of the compute-intensive automotive applications to the replaceable resource modules.

11. A computer program product comprising program code configured to perform the method of claim 10.

12. A non-transitory computer-readable storage medium comprising instructions, which when executed by processing circuitry, cause the processing circuitry to perform the method of claim 10.
